(19) United States
(12) Patent Application Publication
(10) Pub. No.: US 2014/0377891 A1
(43) Pub. Date: Dec. 25, 2014

(54) CHARGED PARTICLE BEAM IRRADIATION APPARATUS AND METHODS RELATED THERETO

(71) Applicant: CANON KABUSHIKI KAISHA, Tokyo (JP)

(72) Inventors: Go Tsuchiya, Tochigi-shi (JP); Wataru Yamaguchi, Utsunomiya-shi (JP)

(21) Appl. No.: 14/311,092

(22) Filed: Jun. 20, 2014

(30) Foreign Application Priority Data
Jun. 24, 2013 (JP) 2013-131659
Mar. 11, 2014 (JP) 2014-048125

(51) Int. Cl. H01J 37/244; H01J 37/317; H01L 21/66

(52) U.S. Cl. CPC H01J 37/244; H01L 22/12; H01J 37/3174
USPC 438/17; 250/200

(57) ABSTRACT

A charged particle beam irradiation apparatus, which irradiates a substrate with a charged particle beam, includes a capacitance sensor and an optical sensor configured to measure a surface position of the substrate, a storage unit configured to store respective measurement values of the surface position of the substrate measured by the optical sensor and the capacitance sensor, and a calculation unit configured to obtain surface position data of the substrate, in which the calculation unit obtains a correction amount by using respective measurement values of the surface position measured by the capacitance sensor and the optical sensor in a region within a scribe line formed on the substrate, which are stored in the stored unit, and applies the correction amount to the measurement value of the surface position measured by the capacitance sensor, to obtain the surface position data of the substrate.

### BACKGROUND OF THE INVENTION

1. Field of the Invention

The present invention generally relates to particle beam irradiation, and specifically it relates to a charged particle irradiation apparatus that irradiates a substrate with a charged particle beam, it also relates to a charged particle beam irradiation method, and to a method for manufacturing a device that generates a charged particle beam.

2. Description of the Related Art

To form a desirable circuit pattern in a lithography process for manufacturing a device such as a semiconductor integrated circuit, it is important to align a surface of a substrate with a focusing position of a beam such as a light beam or an electron beam with high accuracy.

As one method for measuring a surface position, there is a technique for obtaining a distance in an optical axis direction from an optical system to a surface of a substrate (hereinafter referred to as a surface position) by using an optical sensor and a capacitance sensor, as discussed in Japanese Patent Application Laid-Open No. 2001-143991. A difference between measurement values obtained when the optical sensor and the capacitance sensor measure a surface position at the same point is stored as an error amount by the capacitance sensor, and the measurement value of the surface position measured by the capacitance sensor is corrected by using the error amount.

The technique discussed in Japanese Patent Application Laid-Open No. 2001-143991 presupposes that the optical sensor can accurately measure a surface position of a surface to be measured. However, the technique does not consider that a measurement error easily occurs in the measurement value obtained by the optical sensor due to the density of a pattern in a layer formed on the substrate. Thus, in a method for measuring the surface position discussed in Japanese Patent Application Laid-Open No. 2001-143991, there is a possibility that a measurement error by the optical sensor may be added to the error depending on measurement positions.

### SUMMARY OF THE INVENTION

The present invention is directed to a charged particle beam irradiation apparatus capable of obtaining surface position data in even if measurement errors are made by an optical sensor.

According to an aspect of the present invention, a charged particle beam irradiation apparatus, which irradiates a substrate with a charged particle beam, includes a capacitance sensor and an optical sensor configured to measure a surface position of the substrate, a storage unit configured to store respective measurement values of the surface position of the substrate measured by the optical sensor and the capacitance sensor, and a calculation unit configured to obtain surface position data of the substrate, in which the calculation unit obtains a correction amount using respective measurement values of the surface position measured by the capacitance sensor and the optical sensor in a region within a scribe line formed on the substrate, which are stored in the stored unit, and applies the correction amount to the measurement value of the surface position measured by the capacitance sensor, to obtain the surface position data of the substrate.

Further features of the present invention will become apparent from the following description of exemplary embodiments (with reference to the attached drawings).

### BRIEF DESCRIPTION OF THE DRAWINGS

FIG. 1 illustrates a configuration of a drawing apparatus according to a first exemplary embodiment.

FIGS. 2A, 2B, and 2C illustrate different views of a mark region.

FIGS. 3A and 3B illustrate a measurement error by a capacitance sensor at each position of a wafer.

FIG. 4 is a flowchart illustrating processing in a second exemplary embodiment.

FIG. 5 is a flowchart illustrating processing in a third exemplary embodiment.

FIG. 6 is a flowchart illustrating processing in a fourth exemplary embodiment.

FIG. 7 illustrates an example of a method for manufacturing a device.

### DESCRIPTION OF THE EMBODIMENTS

Various exemplary embodiments, features, and aspects of the invention will be described in detail below with reference to the drawings.

A drawing apparatus, which draws a pattern by using one focused electron beam, will be described as an exemplary embodiment of a charged particle beam irradiation apparatus according to the present invention. However, the number of electron beams is not necessarily limited to this. An ion beam may be used as a charged particle beam other than an electron beam. Further, the present invention is applicable to various types of apparatuses that perform processing and measurement by using the charged particle beam.

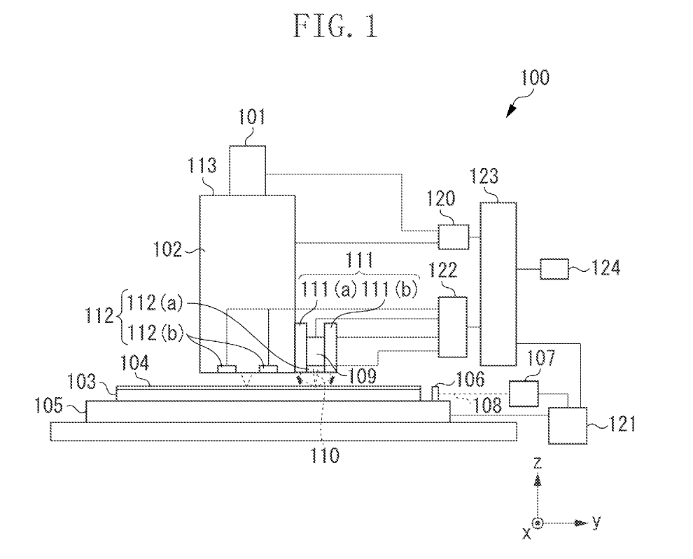

A configuration of a drawing apparatus 100 according to a first exemplary embodiment will be described below with reference to FIG. 1. An electron source 101 generates an electron beam. The generated electron beam is incident on an electron optical system 102. The electron optical system 102 serving as a charged particle optical system focuses the electron beam on a resist 104 applied to a surface of a wafer (substrate) 103.

The resist 104 includes a conductive material layer which could form an equipotential surface on the substrate. Examples include a nonconductive resist coated with a conductive material or a conductive resist could be used for resist 104 to prevent charging. A molecule composing a antistatic layer is preferably a water-soluble polymer that is easily stripped after drawing, and in addition a conductive polymer including a Broensted acid group such as a sulfonic acid group or a carboxylic acid group. Examples include a copolymer such as poly (isothianaphthene sulfonic acid), poly(aniline sulfonic acid), or poly(thiophene alkyl sulfonic acid) or their salt structures.

The electron optical system 102 includes an electron lens system and a deflector (not illustrated). The electron lens system forms the electron beam into a desired shape and the deflector scans the electron beam in an X-axis direction and a Y-axis direction on the resist 104 upon receipt of an instruction from a control unit 120 that controls the electron optical system 102.

A stage 105 is driven in the X-axis direction, the Y-axis direction, and a Z-axis direction according to an instruction from a control unit 121 that controls the stage 105 while retaining the wafer 103. A moving mirror 106 is installed at a position different from the wafer 103 on the stage 105. A laser beam 108 from a laser interferometer 107 is incident on the moving mirror 106, and a position of the stage 105 is measured by using reflected light from the moving mirror 106. The control unit 121 controls the stage 105 based on a measurement value by the laser interferometer 107.

An alignment measurement unit 109 is in the vicinity of the electron optical system 102. The alignment measurement unit 109 measures a position of an alignment mark formed on the wafer 103 by using a light beam 110 for the alignment measurement unit 109, and aligns a position of the wafer 103 in the X-axis direction and the Y-axis direction. Light beam 110 in a wavelength band of 450 nm or more is used so that the resist 104 may not react therewith.

As a unit for measuring a surface position of the wafer 103, drawing apparatus 100 has an optical sensor 111 and a capacitance sensor 112 (two types of measurement units) that differs in charging characteristics, from the optical sensor 111. Thus, the two types of surface position measurement devices having different characteristics in terms of charging. The term “having difference characteristics in terms of charging” indicates whether a main cause of the measurement error is the amount of electric charge stored on the surface of the substrate 103 in characteristics of the measurement device, and does not indicates a difference in error level between measurement devices of the same type.

The optical sensor 111 includes a light projection system 111(a) and a light receiving system 111(b), respectively, on side surfaces of the alignment measurement unit 109. The light projection system 111(a) reflects light on a surface of the resist 104, and the light receiving system 111(b) detects the reflected light, to measure a surface position of the wafer 103.

Light in a wavelength band of 450 mm or more is used for measuring the surface position by the optical sensor 111 so that the resist 104 may not react therewith. To reduce variations in a measurement error caused by a difference in reflectance which depends on a wavelength band of a light source to be used or a measurement error caused by the density of a pattern formed on the substrate, light having a wideband wavelength of 450 nm to 800 nm is preferably used as the light source.

The capacitance sensor 112 obtain a measurement value of the surface position, involving a measurement error caused by charging of the conductive material. The capacitance sensor 112 includes a capacitance sensor 112(a) and capacitance sensors 112(b) respectively arranged at two positions, i.e., at a lower end of the alignment measurement unit 109 and a lower end of a housing 113 that houses the electron optical system 102. A relational equation C=(∈·S)/Z is used when the capacitance sensor 112 measures the surface position, where ∈ is a dielectric constant between respective electrodes of the resist 104 and the capacitance sensor 112, S is the measurement area of the capacitance sensor 112, and Z is an average surface position per measurement area S of the wafer 103 that is coated with the resist 104 serving as a conductive material.

The capacitance sensor 112(a) is used to obtain a correction offset value, described below. The capacitance sensor 112(a) is in a ring shape having a hole provided at its center. The light beam 110 for the alignment measurement unit 109 can pass through a central part of the hole. Thus, a surface position in the same region can be measured without substantial movement of the wafer 103 during the measurements by the alignment measurement unit 109, the optical sensor 111, and the capacitance sensor 112(a).

On the other hand, the capacitance sensors 112(b) are used when the surface position is measured during the drawing of the pattern by using the electron beam. A measurement value by the capacitance sensor 112 is an average of measurement areas. Thus, a plurality of small capacitance sensors 112(b) is also preferably arranged to measure a surface position in a wide band in a short period of time.

The alignment measurement unit 109, the optical sensor 111, and the capacitance sensor 112 are connected to a control unit 122 that controls the measurement units. The control unit 122 is connected to a controller 123. The control unit 122 instructs each of the measurement units to perform the measurement upon receipt of an instruction from the controller 123, and transmits a result obtained from the measurement unit to the controller 123.

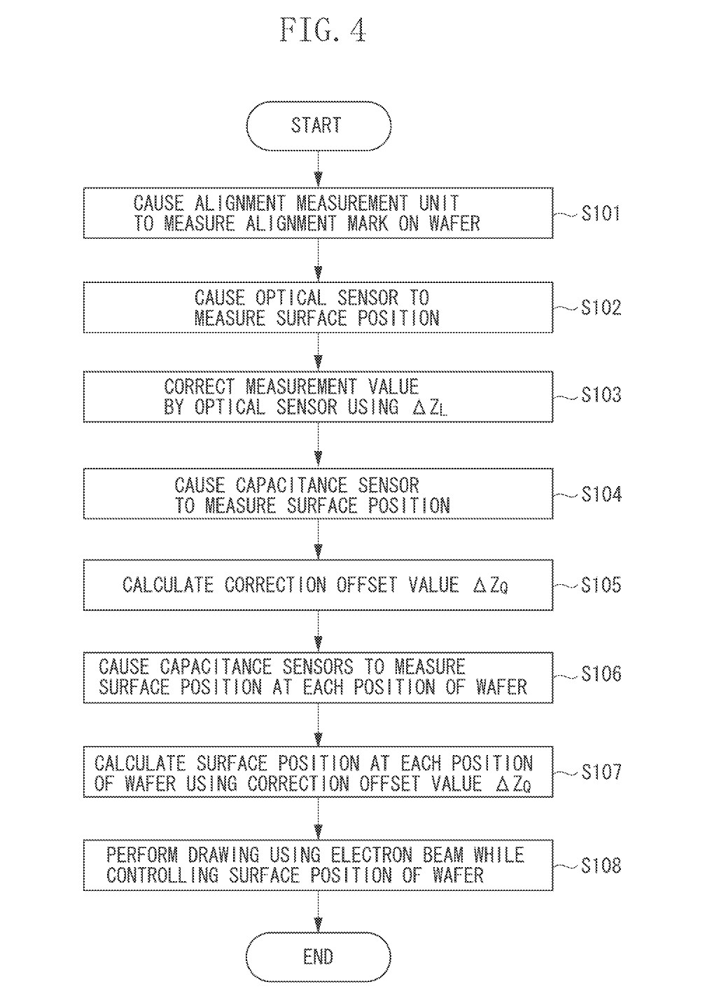

The controller 123 is connected to the control unit 120, the control unit 121, the control unit 122, and a storage unit 124. A central processing unit (CPU) implemented by one or more microprocessor included in the controller 123 issues an instruction to each of the control units, and executes programs, illustrated in flowcharts of FIGS. 4, 5, and 6, which are stored in the storage unit 124. Examples of storage unit 124 include, but are not limited to, a magnetic storage device such as a hard disk drive (HDD), and a solid state storage device such as a solid state disk (SSD).

In this case, the CPU also serves as a calculation unit for performing calculation processing based on a measurement value obtained from each of measurement operations. For example, the CPU obtains surface position data representing an actual surface position, and obtains a correction amount required to obtain the surface position data. By the above functions, the controller 123 integrates operations relating to the drawing apparatus 100, e.g., a drawing operation by using an electron beam, a measurement operation, and stage driving.

The storage unit 124 stores a drawing pattern, a measurement error ΔZ_{L} made by the optical sensor 111, and the programs illustrated in the flowcharts of FIGS. 4, 5, and 6. Further, the storage unit 124 successively stores a measurement value obtained by each of the measurement units, a calculation result made by the controller 123, and a correction amount obtained by the capacitance sensor 112.

The electron source 101, the electron optical system 102, the wafer 103, the stage 105, the laser interferometer 107, the alignment measurement unit 109, the optical sensor 111, and the capacitance sensor 112 are arranged within a vacuum chamber that is evacuated by a vacuum pump (not illustrated).

A configuration of the drawing apparatus 100 has been described above. Handling of a measurement value by the optical sensor 111 will be described below.

A relationship of Z_{L}=A×Z+ΔZ_{L} holds using an actual surface position Z, a surface position Z_{L} to be measured by the optical sensor 111, a measurement error A, and a measurement error ΔZ_{L}. The measurement error A occurs when the stage 105 is moved in the Z-axis direction when a measurement point (X, Y) on the wafer 103 by the optical sensor 111 remains fixed. On the other hand, the measurement error ΔZ_{L} occurs when a relative distance in the Z-axis direction between the wafer 103 and the optical sensor 111 remains fixed and the measurement point (X, Y) is moved.

The measurement error A and the measurement error ΔZ_{L} may occur due to interference between reflected light from a boundary surface of each of layers below the resist 104 and reflected light from a surface of the resist 104. Thus, the quality of a material in the layer below the resist 104 and the density of a pattern formed on the wafer 103 affect the measurement errors.

The measurement error A is corrected by using a measurement result by the measurement unit capable of measuring a position of an object with high accuracy, for example, the laser interferometer 107. The stage 105 is moved by a known amount AZ in the Z-axis direction while the laser interferometer 107 is used. A movement amount ΔZ_{L} between measurement values of the surface position, which is measured before and after the movement, is measured, and the measurement error A is corrected by using A=ΔZ_{L}/ΔZ. Thus, the measurement error A can be corrected even if the actual surface position Z is unclear. In the following description, the error A in the measurement value when the optical sensor 111 measures the surface position has already been corrected with respect to the actual surface position Z, and only the movement amount ΔZ_{L} is handled as a measurement error, where the surface position is measured as Z_{L}=Z+ΔZ_{L}.

The measurement error ΔZ_{L} by the optical sensor 111 has been previously obtained before the measurement of the surface position and stored in the storage unit 124. The measurement error ΔZ_{L} can be obtained from a difference between the surface position measured by the optical sensor 111 and a surface position where drawing with high resolution can be performed which can be obtained by drawing the same pattern at different surface positions and by evaluating shapes of semiconductor layers formed as a result of the drawing.

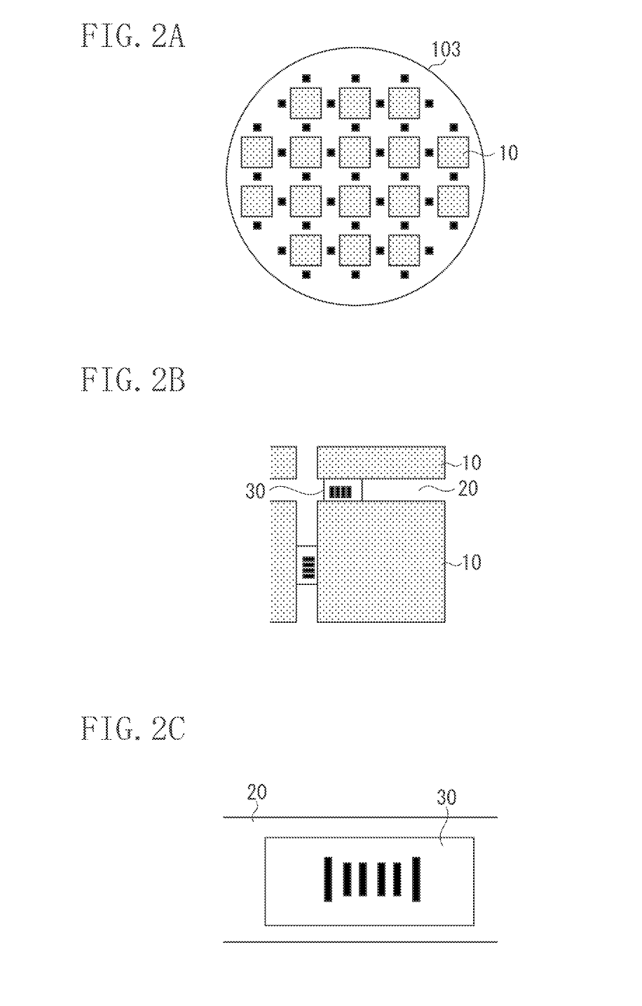

The measurement of the surface position by the optical sensor 111 is preferably performed in a narrow range or a region where a value of the measurement error ΔZ_{L} is easily reproduced between different measurement positions. The region where the value of the measurement error ΔZ_{L} is easily reproduced will be described with reference to FIGS. 2A to 2C. FIG. 2A illustrates the entire wafer 103, FIG. 2B is an enlarged view of FIG. 2A, and FIG. 2C is an enlarged view of FIG. 2B. An example of the region where the value of the measurement error ΔZ_{L} is easily reproduced is a scribe line 20 provided between shot regions 10 (regions corresponding to one or a plurality of chip regions to be formed); another example is more preferably a pattern formation inhibition region (a mark region) 30 within the scribe line 20. The scribe line separates adjacent shot region 10 within a wafer, therefore, in the scribe line 20, a user does not generally form a circuit pattern. Thus, a variation in the measurement error ΔZ_{L} that occurs due to the density of a pattern of a metal wiring, which is a major factor of the measurement error ΔZ_{L}, does not easily occur even if the measurement point (X, Y) varies.

Particularly, as illustrated in FIGS. 2B and 2C, the inhibition region 30 within the scribe line 20 is an alignment mark and a region around the alignment mark, is formed by a structure determined for each drawing apparatus, and is not pattern-formed by the user. Thus, when the same optical sensor 111 measures the surface position, the same measurement error is easily reproduced. Moreover, the measurement error ΔZ_{L} becomes easy to be previously obtained and stored in the storage unit 124.

The inhibition region 30 is a region surrounded by a length of 60 μm or more and 80 μm or less in a widthwise direction and a length of 250 μm or more and 500 μm or less in a lengthwise direction, for example. The specific size of the inhibition region 30 is determined in exact detail depending on the width of the scribe line 20 and the type of the alignment mark. For example, the length in the widthwise direction may be not less than the half of the width of the scribe line 20 and not more than the width of the scribe line 20. If the width of a spot region in the optical sensor 111 is larger than the width of the scribe line 20, the spot region may be made narrow by using a diaphragm or the like.

Further, a method for measuring the surface position by using the optical sensor 111 and the capacitance sensor 112 will be described prior to description of a processing content of the drawing apparatus 100.

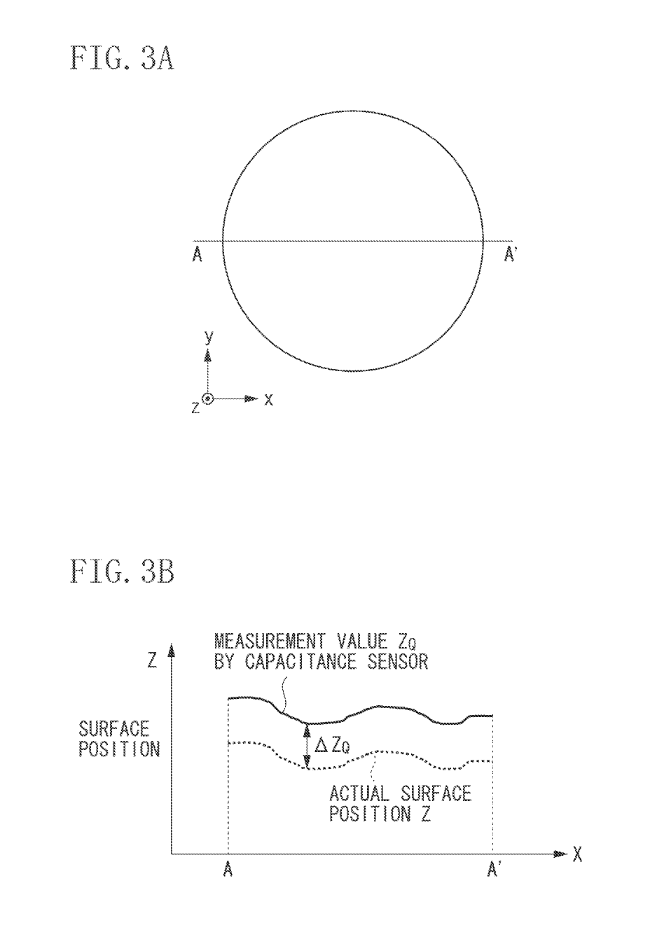

FIG. 3A illustrates the wafer 103 as viewed from the side of the electron optical system. A vertical axis illustrated in FIG. 3B represents a surface position of the wafer 103 in a cross section A-A′ illustrated in FIG. 3A. A measurement value Z_{Q} of the surface position of the wafer 103 by the capacitance sensor 112 includes not only an actual surface position Z but also a measurement error ΔZ_{Q} caused by charging a surface of the wafer 103. The measurement error ΔZ_{Q} caused by the charging becomes a substantially uniform value at each point in the cross section A-A′ by using a conductive material as the resist 104. The actual surface position Z is represented by Z=Z_{Q}−ΔZ_{Q} where Z_{Q} is the measurement value by the capacitance sensor 112.

More specifically, if the measurement error ΔZ_{Q} corresponding to a difference between the measurement value Z_{Q} by the capacitance sensor 112 and the actual surface position Z is obtained in at least one region on the wafer 103, the measurement error ΔZ_{Q} can be set to a correction offset value (a correction amount). The correction offset value ΔZ_{Q} is applied to a result of the measurement of the surface position on the entire surface of the wafer 103 by the capacitance sensor 112 so that the surface position measurement result can be corrected with high accuracy. Since the actual surface position at each point of the wafer 103 is obtained, an inclination component of the wafer 103 can also be together obtained.

The program illustrated in the flowchart of FIG. 4, which is performed by the controller 123 to measure the surface position of the wafer 103 with high accuracy, will be described in detail. Processing illustrated in FIG. 4 is processing relating to a case where a surface position on the entire surface of the wafer 103 is obtained prior to drawing. The storage unit 124 previously stores a measurement error ΔZ_{L} obtained in an alignment mark by the optical sensor 111.

In step S101, the controller 123 causes the control unit 121 to move the stage 105 so that an alignment mark is positioned in a measurement region of the alignment measurement unit 109, and causes the alignment measurement unit 109 to measure a surface position in the alignment mark. The controller 123 stores the measured position of the alignment mark in the storage unit 124. The controller 123 performs a similar operation for other regions where an alignment mark is formed, and aligns the wafer 103 in the X- and Y-axis directions with an electron beam based on a measurement result.

In step S102, the controller 123 causes the optical sensor 111 to measure the surface position in the alignment mark, which has been measured in step S101, and stores a measurement result in the storage unit 124. The optical sensor 111 is in the vicinity of the alignment measurement unit 109. Thus, the controller 123 can measure the surface position without subsequently moving the stage 105 after the operation in step S101.

In step S103, the controller 123 further calculates an actual surface position Z in the alignment mark by using a measurement value of the surface position in the alignment mark, which has been measured in step S102, and obtains data corresponding to the actual surface position Z in the alignment mark by calculating Z=Z_{L}−A_{L}, where ΔZ_{L} is the measured error and the surface position Z_{L} measured by the optical sensor 111.

In step S104, the controller 123 causes the capacitance sensor 112(a) provided in a lower part of the alignment measurement unit 109 to measure a surface position in the same mark as the alignment mark, the surface position of which has been measured in step S102, and stores a measurement result Z_{Q} obtained by the capacitance sensor 112(a) in the storage unit 124.

In step S105, the controller 123 calculates a correction offset value ΔZ_{Q} by the capacitance sensor 112, calculates ΔZ_{Q}=Z_{Q}−Z where Z is the actual surface position, which has been obtained from the measurement result by the optical sensor 111 in step S102, and the measurement result Z_{Q} by the capacitance sensor 112(a), which has been obtained in step S104, to obtain the correction offset value ΔZ_{Q}, and stores the correction offset value ΔZ_{Q} in the storage unit 124.

In step S106, the controller 123 causes the plurality of capacitance sensors 112(b) to measure a surface position at each position of the wafer 103 after causing the control unit 121 to move the wafer 103 to a lower part of the optical system 102. The surface position of the wafer 103 is measured at all positions required to grasp the surface position on the entire surface of the wafer 103. The controller 123 stores a measured surface position Z_{Q}(i) in the storage unit 124, where (i) is each measurement position.

In step S107, the controller 123 obtains a surface position Z(i) at each position of the wafer 103 by calculating Z(i)=Z_{Q}(i)−ΔZ_{Q}, where ΔZ_{Q} is the above-mentioned correction offset value.

In step S108, the controller 123 starts to perform drawing by using an electron beam while causing the control unit 121 to adjust the position of the stage 105 so that the surface of the wafer 103 is positioned relative to a focus position of an electron beam based on the surface position Z(i) serving as surface position data, which has been obtained in step S107. When the controller 123 finishes drawing all patterns, the program ends.

The processing relating to the case where the drawing apparatus 100 according to the first exemplary embodiment obtains the surface position of the entire surface of the wafer 103 has been described above.

The surface of the wafer 103 is covered with a conductive material, so that charge, which is inherently likely to accumulate on the surface of the wafer 103 locally, is uniformly dispersed. A correction offset value obtained in at least one region is applied to the entire surface of the wafer 103 by using the characteristic of the resist 104 including the conductive material. Thus, drawing can be performed with high accuracy by correcting an error caused by the charging in measuring the surface position. The correction is performed, considering the measurement error by the optical sensor 111. Therefore, the error caused by the measurement of the surface position can be more reduced than in the conventional technique.

In step S104, the capacitance sensors 112(b) may be used to measure the surface position in the alignment mark. On the other hand, in step S106, the capacitance sensor 112(a) may be used to measure the surface position at each position of the wafer. However, the measurement region in step S106 is wider than that at the time when the surface position is measured in step S104. Thus, more capacitance sensors 112 are preferably used. Therefore, when the capacitance sensors 112(b) at the lower end of the electron optical system providing a more space than that in the lower part of the alignment measurement unit 109 are used, a period of time required for the measurement is shortened so that throughput can be improved.

If the measurement error ΔZ_{L} is obtained in a region other than the inhibition region 30 within the scribe line 20, a surface position measurement value required to calculate the correction offset value ΔZ_{Q} is measured in the region other than the inhibition region 30 within the scribe line 20. If the measurement error ΔZ_{L} is obtained in the inhibition region 30, the surface position measurement value required to calculate the correction offset value ΔZ_{Q} is measured in the inhibition region 30.

A second exemplary embodiment differs from the first exemplary embodiment in that the processing in steps S106 and S107 in the flowchart illustrated in FIG. 4 is performed, as needed, concurrently with the drawing operation in step S108. More specifically, the capacitance sensors 112(b) measure a surface position in a non-drawing region while drawing is performed. Further, the measurement value is corrected by using the correction offset value ΔZ_{Q}, which has been obtained in step S105, before a drawing operation at the measured surface position is started, to obtain surface position data.

According to the present exemplary embodiment, throughput can be improved compared with that at the time when the surface position on the entire surface of the wafer 103 is obtained prior to the drawing, like in the first exemplary embodiment.

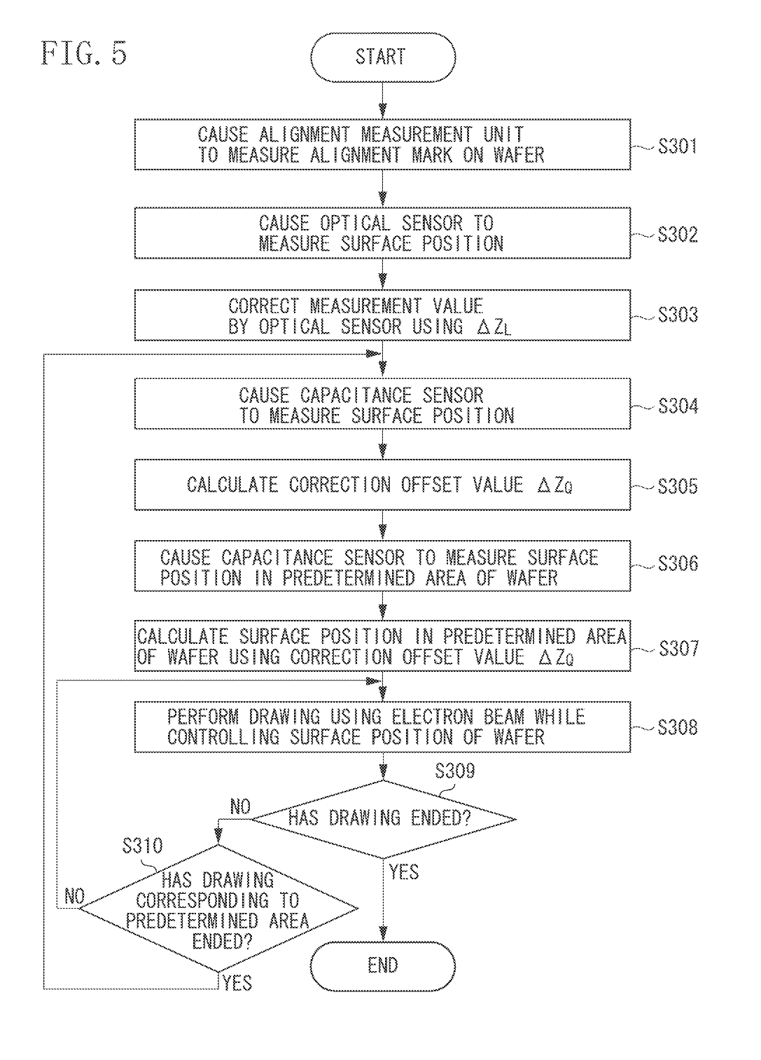

The drawing apparatus 100 according to a third exemplary embodiment updates a correction offset value depending on an amount of the charging that changes with time. The third exemplary embodiment differs from the other exemplary embodiments in that the storage unit 124 stores the program illustrated in the flowchart of FIG. 5, and the controller 123 executes the program. Processing in steps S301 to S305 is similar to the processing in steps S101 to S105 in the flowchart illustrated in FIG. 3, and hence description thereof is not repeated.

In step S306, the controller 123 causes the capacitance sensors 112(b) to measure a surface position within a predetermined region of the wafer 103. The predetermined region is a shot region corresponding to one row, a shot region corresponding to a predetermined number of rows, or a region where the total amount of incident energy reaches a predetermined amount. The predetermined region may be a region where drawing is predicted to be performed within a predetermined period of time.

In step S307, the controller 123 applies a correction offset value ΔZ_{Q} to the predetermined region, where the surface position has been measured in step S306, to calculate the surface position in the predetermined region of the wafer 103. In step S308, the controller 123 then starts to perform drawing while the control unit 121 controls the surface position of the wafer 103.

In step S309, the controller 123 determines whether drawing corresponding to all drawing regions has ended. If it is determined that the drawing corresponding to all the drawing regions has not yet ended (NO in step S309), the processing proceeds to step S310. In step S310, the controller 123 determines whether drawing corresponding to the predetermined region, where the surface position has been measured in step S306, has ended. If it is determined that the drawing corresponding to the predetermined region has not ended (NO in step S310), the processing returns to step S308. In step S308, the controller 123 continues to perform drawing.

If it is determined that the drawing corresponding to the predetermined region has ended (YES in step S310), the processing returns to step S304. In step S304, the controller 123 causes the capacitance sensor 112(a) to measure again a surface position of an alignment mark that has been measured in step S302. In step S305, the controller 123 calculates the correction offset value ΔZ_{Q} again, and updates the correction offset value ΔZ_{Q} stored in the storage unit 124. Steps S303 to S310 are repeated in a similar manner.

If it is determined that the drawing corresponding to all the drawing regions has ended (YES in step S310), the program ends.

Thus, the present exemplary embodiment differs from the other exemplary embodiments in that the correction offset value ΔZ_{Q} is updated. An amount of charge to be stored in the wafer 103 increases according to an amount of energy falling on the substrate 103, a period of time during which the energy is falling, and a region where the energy is falling. If an amount of charging on the wafer 103 drastically changes with time, therefore, the present exemplary embodiment is preferably used.

In a fourth exemplary embodiment, a surface position can be obtained with higher accuracy by using a measurement value in a region where reproducibility of a measurement error ΔZ_{L} is higher than those in the first to third exemplary embodiments.

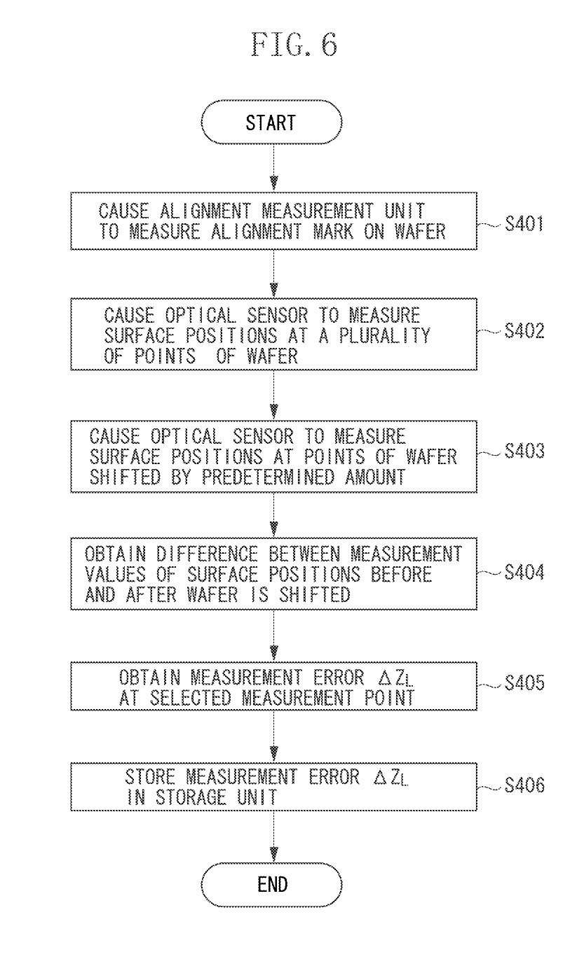

In the drawing apparatus 100 according to the present exemplary embodiment, a storage unit 124 stores the program to be executed until a measurement error ΔZ_{L} is obtained that is illustrated in the flowchart of FIG. 6, and a controller 123 executes the program.

Step S401 is similar to step S101, and hence description thereof is not repeated. In step S402, the controller 123 causes the optical sensor 111 to measure surface positions at a plurality of measurement points within the inhibition region 30 which excludes an alignment mark. In step S403, the controller 123 further causes the optical sensor 111 to measure surface positions at measurement points, which are shifted by a predetermined amount in a predetermined direction, respectively, from the measurement points at which the surface positions have been measured in step S402.

In step S404, the controller 123 then obtains a difference between measurement values of the surface positions, which have been measured by the optical sensor 111 before and after the wafer 103 is shifted. If the difference between the measurement values before and after the wafer 103 is shifted is small, substantially the same measurement errors ΔZ_{L} are reproduced. On the other hand, if the difference between the measurement results becomes large, the measurement error ΔZ_{L} is not easily reproduced even in the inhibition region 30 compared with a region where the difference between the measurement results is small.

In step S405, the controller 123 selects at least one of the measurement points where the difference between the measurement values before and after the wafer 103 is shifted becomes smaller than a predetermined value previously set. In step S406, the controller 123 further obtains the measurement error ΔZ_{L} at the measurement point, and stores the obtained measurement error ΔZ_{L} in the storage unit 124. A method for obtaining the measurement error ΔZ_{L} is similar to that in the above-mentioned method, and hence description thereof is not repeated.

Processing similar to the processing in steps S101 to S105 in the first exemplary embodiment is performed by using the measurement error ΔZ_{L} obtained at the selected measurement point, to obtain a correction offset value ΔZ_{Q}. In this case, when the surface position is measured in a region where measurement is reproducible through the processing in steps S401 to S404 within the inhibition region 30, a highly accurate correction offset value ΔZ_{Q} can be obtained. Further, a surface position at each of the measurement points of the wafer 103 can be obtained with high accuracy.

In the present exemplary embodiment, the measurement value of the surface position in the region where measurement is actually reproducible is used after it is confirmed that the measurement error ΔZ_{L} by the optical sensor 111 is reproduced. Thus, a deviation of the measurement value obtained by the optical sensor 111 before the measurement value is corrected by using the measurement error ΔZ_{L} can be reduced. Accordingly, the correction offset value ΔZ_{Q} and further surface position data Z(i) can be obtained with higher accuracy than those in the first exemplary embodiment.

Particularly when a slight positioning control error occurs with respect to the stage 103 and when the optical sensor 111 measures a surface position in an alignment mark, a method in the present exemplary embodiment is preferably used. Further, materials which show a small difference in reflectance between the alignment mark and a region around the alignment mark, are preferably used. Thus, a position where the same measurement error ΔZ_{L} occurs can be more easily searched for than that at the time when a similar measurement is performed within a shot region where an unknown pattern is formed.

Finally, another exemplary embodiment, which is commonly applicable to the exemplary embodiments will be described. The plurality of capacitance sensors 112 arranged in a lower part of the alignment measurement unit 109 and in a lower part of the electron optical system 102 may respectively have different correction offset values ΔZ_{Q} as an individual difference of the sensor. In this case, all the capacitance sensors 112 used for measurement need to measure a surface position in the same alignment mark and previously correct the measured surface position.

The correction offset value ΔZ_{Q} may be calculated by using an average of measurement values of surface positions in a plurality of regions where measurement is reproducible (S102, S104, S302, and S304). If the film thickness of the resist 104 affects an error in measuring the surface position by the capacitance sensor 112, the correction offset value ΔZ_{Q} is preferably obtained by weighting a distance from the center of the wafer 103 to a measurement region.

The wafers 103, which have been conveyed in the same conveyance path, are substantially equal in amount of charging. Thus, a correction offset value ΔZ_{Q} obtained by using the wafer 103 to be first processed in each lot is preferably applied to the other wafers 103 in the same lot. Thus, throughput can be improved compared with that at the time when a correction offset value ΔZ_{Q} in each of the wafers 103 is calculated.

An exemplary arrangement of the alignment measurement unit 109, the optical sensor 111, and the capacitance sensor 112(a) is illustrated in FIG. 1. There is a measurement point by the optical sensor 111 within a measurement region of the capacitance sensor 112(a) so that the number of times the wafer 103 moves is reduced when each of the measurement units measures the surface position (S101 to S104 and S301 to S304). Thus, throughput can be improved.

While the respective measurements by the alignment measurement unit 109, the optical sensor 111, and the capacitance sensor 112(a) are performed in this order in each of the exemplary embodiments, measurements are preferably performed by two or more types of sensors substantially concurrently. Thus, a decrease in throughput due to the time necessary for each measurement can be suppressed.

While the control unit 121 controls the surface position of the wafer 103 after the surface position in the entire surface of the wafer 103 has been corrected, the control unit 120 may control a position where an electron beam is focused if no other adverse effect occur.

As described above, according to each of the above-mentioned exemplary embodiments, the surface position on the surface of the wafer 103 can be obtained considering with the measurement error ΔZ_{L} of the optical sensor 111 and an effect of charging received by the capacitance sensor 112. The measurement value of the surface position by the optical sensor 111 is corrected in a region where the measurement error ΔZ_{L} is easily reproduced so that the accuracy of the correction amount ΔZ_{Q} by the capacitance sensor 112 may not vary depending on positions.

Further, the capacitance sensor 112 can also be arranged in a narrow space, and can measure the surface position, as needed, while drawing is performed. Further, the optical sensor 111 and the capacitance sensor 112 can be used even in a vacuum where usable measurement apparatuses are limited.

In the charged particle beam irradiation apparatus according to the present invention, the charged particle beam can be irradiated to the substrate using the surface position data in consideration of the measurement error of the optical sensor. If the present invention is used for an electron beam drawing apparatus, for example, therefore, a desired pattern can be drawn on an object to be radiated on a substrate by correcting an error in measuring a surface position.

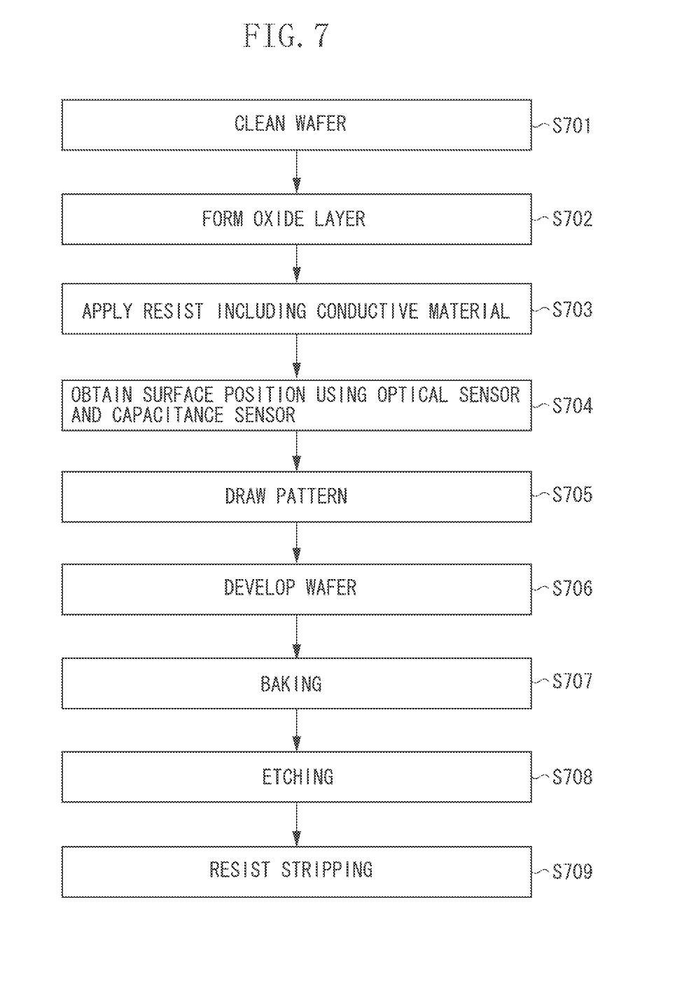

FIG. 7 illustrates an example of a method for manufacturing a device according to the present invention. Examples of devices that can be manufactured by using the disclosed charged particle beam irradiation apparatus include, e.g., a semiconductor integrated circuit, a liquid crystal display, a compact disk (CD)-rewritable, or a photomask. The method for manufacturing the device includes steps of S701: selecting and cleaning a desired wafer or substrate; S702: forming an oxide layer on the cleaned wafer (e.g., by chemical vapor deposition); S703: applying a resist including a conductive polymer to the wafer; S704: obtaining a surface position based on the above-described exemplary embodiments, and S705: drawing a pattern on the wafer, and S706: developing the wafer where the pattern is drawn. Further, the method may include other known processing steps, including, but not limited to, S707: baking, S708: etching, and S709: performing resist stripping. Moreover, the method may include, e.g., oxidation, film formation, evaporation, doping, flattening, etching, resist stripping, dicing, bonding, and packaging. The wafer may be replaced with a substrate such as a glass.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2013-131659 filed Jun. 24, 2013, and Japanese Patent Application No. 2014-048125 filed Mar. 11, 2014, which are hereby incorporated by reference herein in their entirety.

What is claimed is:

1. A charged particle beam irradiation apparatus, which irradiates a substrate with a charged particle beam, comprising:
a capacitance sensor and an optical sensor configured to measure a surface position of the substrate;
a storage unit configured to store respective measurement values of the surface position of the substrate measured by the optical sensor and the capacitance sensor; and
a calculation unit configured to obtain surface position data of the substrate,
wherein the calculation unit obtains a correction amount by using the respective measurement values of the surface position measured by the capacitance sensor and the optical sensor in a region within a scribe line formed on the substrate, which are stored in the storage unit, and applies the correction amount to the measurement value of the surface position measured by the capacitance sensor, to obtain the surface position data of the substrate.

2. The charged particle beam irradiation apparatus according to claim 1, wherein the storage unit stores a measurement error in the measurement value of the surface position measured by the optical sensor in the region within the scribe line, and the calculation unit obtains the correction amount by using the measurement error and the respective measurement values of the surface position of the substrate measured by the optical sensor and the capacitance sensor.

3. The charged particle beam irradiation apparatus according to claim 2, wherein the calculation unit obtains the correction amount by using a difference between a value obtained by correcting the measurement error in the measurement value of the surface position measured by the optical sensor and the measurement value of the surface position measured by the capacitance sensor.

4. The charged particle beam irradiation apparatus according to claim 1, wherein the capacitance sensor and the optical sensor measure at least a mark region within a scribe line.

5. The charged particle beam irradiation apparatus according to claim 4, wherein a length in a widthwise direction of the mark region is not less than the half of a width of the scribe line and not more than the width of the scribe line.

6. The charged particle beam irradiation apparatus according to claim 4, wherein a length in a lengthwise direction of the mark region is 250 μm or more and 500 μm or less.

7. A charged particle beam irradiation apparatus, which irradiates a substrate with a charged particle beam, comprising:
an optical sensor and a capacitance sensor configured to measure a surface position of the substrate; and
a calculation unit configured to obtain surface position data of the substrate,
wherein the calculation unit applies a correction amount obtained by using respective measurement values of the surface position measured by the optical sensor and the capacitance sensor in a region within a scribe line formed on the substrate, to a measurement value of the surface position measured by the capacitance sensor, to obtain the surface position data of the substrate.

8. A method for manufacturing a device, comprising:
forming a conductive material layer on a surface of a substrate; and
irradiating the substrate with a charged particle beam by using a charged particle beam irradiation apparatus,
wherein the charged particle beam irradiation apparatus, which irradiates the substrate with the charged particle beam, comprises:
a capacitance sensor and an optical sensor configured to measure a surface position of the substrate;
a storage unit configured to store respective measurement values of the surface position of the substrate measured by the optical sensor and the capacitance sensor; and
a calculation unit configured to obtain surface position data of the substrate, and
the calculation unit obtains a correction amount by using respective measurement values of the surface position measured by the capacitance sensor and the optical sensor in a region within a scribe line formed on the substrate, which are stored in the storage unit, and applies the correction amount to the measurement value of the surface position measured by the capacitance sensor, to obtain the surface position data of the substrate.

9. A charged particle beam irradiation method, comprising:
forming a conductive material layer on a surface of a substrate;
performing first measurement for measuring a surface position in at least a region within a scribe line formed on the substrate by using two types of measurement units that differ in charging characteristics;
obtaining a correction amount for correcting a measurement value of the surface position measured by the measurement unit, involving a measurement error caused by charging of the conductive material layer, among the two types of measurement units based on a measurement result in the first measurement;
performing second measurement for measuring a surface position of the substrate having the conductive material layer formed on its surface by using the measurement unit involving the measurement error caused by the charging of the conductive material layer;
obtaining surface position data of the substrate having the conductive material layer formed on its surface based on a measurement result in the second measurement and the correction amount; and
adjusting a surface position corresponding to a focus position of a charged particle beam based on the surface position data, to irradiate the substrate with the charged particle beam.

10. An apparatus for measuring a surface position of a substrate in a vacuum, comprising:
an optical sensor and a capacitance sensor configured to measure the surface position of the substrate; and
a calculation unit configured to obtain surface position data of the substrate,
wherein the calculation unit applies a correction amount obtained by using measurement values of the surface position measured by the optical sensor and the capacitance sensor in a region within a scribe line formed on the substrate, to the measurement value of the surface position of the substrate measured by the capacitance sensor, to obtain the surface position data of the substrate.
